(19) United States
(12) Patent Application Publication
(10) Pub. No.: US 2024/0105652 A1
(43) Pub. Date: Mar. 28, 2024

(54) METHOD OF MANUFACTURING SEMICONDUCTOR DEVICE

(71) Applicant: SK hynix Inc., Icheon-si Gyeonggi-do (KR)

(72) Inventors: Dae Won KIM, Icheon-si Gyeonggi-do (KR); Sung Kyu KIM, Icheon-si Gyeonggi-do (KR)

(73) Assignee: SK hynix Inc., Icheon-si Gyeonggi-do (KR)

(21) Appl. No.: 18/097,931

(22) Filed: Jan. 17, 2023

(30) Foreign Application Priority Data
Sep. 27, 2022 (KR) 10-2022-0122851

(51) Int. Cl. H01L 23/00

(52) U.S. Cl. CPC H01L 24/11; H01L 24/05; H01L 24/13; H01L 2224/0401; H01L 2224/05124; H01L 2224/05644; H01L 2224/05647; H01L 2224/05655; H01L 2224/1111; H01L 2224/11474; H01L 2224/13017; H01L 2224/13147

(57) ABSTRACT

A method of manufacturing a semiconductor device includes forming a first photoresist layer on a substrate and forming a second photoresist layer on the first photoresist layer. The method also includes forming a first dissolvable region having a first width in the first photoresist layer and a second dissolvable region having a second width different from the first width in the second photoresist layer by radiating exposure light to some parts of the second and first photoresist layer. The method further includes forming a second opening in the second photoresist layer and a first opening in the first photoresist layer by developing the second dissolvable region and the first dissolvable region. The method additionally includes forming a conductive bump that fills the first and second openings.

### CROSS-REFERENCE TO RELATED APPLICATION

The present application claims priority under 35 U.S.C. § 119(a) to Korean application number 10-2022-0122851, filed in the Korean Intellectual Property Office on Sep. 27, 2022, the entire disclosure of which is incorporated herein by reference.

### BACKGROUND

The present disclosure relates to a semiconductor technology and, particularly, to a method of manufacturing a semiconductor device including a conductive bump.

As the performance, degree of integration, and speed of semiconductor devices are increased and the sizes of semiconductor devices are reduced, the number of input/output (I/O) terminals for interconnections that are necessary for the semiconductor devices is increased. As high-speed operation and power reduction are required for the semiconductor devices, it becomes necessary to reduce paths for the interconnections. Accordingly, conductive bumps are increasingly adopted for the semiconductor devices as elements for the interconnections. Furthermore, it is necessary to develop a technology in which a larger number of bumps are applied to semiconductor devices.

To apply a larger number of bumps to a semiconductor substrate or semiconductor the that constitutes a semiconductor device, it is necessary to reduce a critical dimension size of bumps. As the critical dimension size of the bumps is reduced, it becomes difficult to maintain bonding integrity between the bumps and the semiconductor die. Accordingly, attempts to improve the bonding strength between the bumps and the semiconductor die by changing shapes of the bumps are being made.

### SUMMARY

A method of manufacturing a semiconductor device in accordance with the present disclosure includes: forming a first photoresist layer on a substrate; forming a second photoresist layer on the first photoresist layer; forming a first dissolvable region having a first width in the first photoresist layer and a second dissolvable region having a second width different from the first width in the second photoresist layer by radiating exposure light to some parts of the second and first photoresist layers; forming a second opening in the second photoresist layer and a first opening in the first photoresist layer by developing the second dissolvable region and the first dissolvable region; and forming a conductive bump that fills the first and second openings.

A method of manufacturing a semiconductor device in accordance with the present disclosure includes: forming a first photoresist layer on a substrate; forming, on the first photoresist layer, a second photoresist layer in which a second diffusion distance at which a second add, that is generated by exposure light incident on a part of the second photoresist layer, is diffused is different from a first diffusion distance at which a first acid, that is generated by the exposure light incident on a part of the first photoresist layer, is diffused in the first photoresist layer; forming, as a result of the incident exposure light, a first dissolvable region having a first width in the first photoresist layer and a second dissolvable region having a second width different from the first width in the second photoresist layer; forming a second opening in the second photoresist layer and a first opening in the first photoresist layer by developing the second dissolvable region and the first dissolvable region; and forming a conductive bump that fills the first and second openings.

### BRIEF DESCRIPTION OF THE DRAWINGS

FIG. 1 is a cross-sectional view illustrating that photoresist layers are formed in a method of manufacturing a semiconductor device according to an embodiment,

FIG. 2 is a diagram illustrating an example of a photoresist which may constitute the photoresist layers in FIG. 1,

FIGS. 3 to 6 are cross-sectional views illustrating that photoresist layers are exposed in a method of manufacturing a semiconductor device according to an embodiment.

FIG. 7 is a cross-sectional view illustrating that openings are formed in photoresist layers in a method of manufacturing a semiconductor device according to an embodiment.

FIG. 8 is a cross-sectional view illustrating that a conductive bump is formed in openings in a method of manufacturing a semiconductor device according to an embodiment,

FIG. 9 is a cross-sectional view illustrating that a solder layer is formed on the conductive bump in FIG. 8.

FIG. 10 is a cross-sectional view illustrating that photoresist layers have been removed from the conductive bump in FIG. 9.

FIG. 11 is a cross-sectional view illustrating that the solder layer in FIG. 10 has been reflowed.

FIG. 12 is a cross-sectional view illustrating a method of manufacturing a semiconductor device according to an embodiment.

FIG. 13 is a block diagram illustrating an electronic system using a memory card including a semiconductor device according to an embodiment.

FIG. 14 is a block diagram illustrating an electronic system including a semiconductor device according to an embodiment.

### DETAILED DESCRIPTION

Terms that are used in the description of examples of this application are terms selected by taking into consideration functions in proposed embodiments, and the meanings of the terms may be different depending on a user, an operator's intention or practice in the technical field. The meaning of a term used follows the definition of the term if the term has been specifically defined in this specification, and may be interpreted as a meaning which may be commonly recognized by those skilled in the art if the term has not been specifically defined.

In the description of examples of this application, terms, such as a “first”, a “second”, a “side”, a “top”, and a “bottom or lower”, are used to distinguish between members and are not used to limit the members themselves or to mean a specific order.

A semiconductor substrate may denote a semiconductor wafer on which electronic parts and elements are integrated. Integrated circuits may be integrated on the semiconductor substrate. The semiconductor substrate may be diced into a plurality of semiconductor chips or a plurality of semiconductor dies.

A semiconductor chip may be a memory chip on which memory devices, such as DRAM, SRAM, NAND flash memory, NOR flash memory, MRAM, ReRAM, FeRAM, or PcRAM, have been integrated. A semiconductor chip may denote a logic die or an ASIC chip, an application processor (AP), a graphic processing unit (GPU), a central processing unit (CPU), or a system on chip (SoC) in which logic circuits have been integrated on a semiconductor substrate.

A semiconductor chip may be a component that constitutes a semiconductor package or a semiconductor product. Semiconductor chips may be applied to information communication devices such as a mobile terminal, bio or health care-related electronic devices, and electronic devices wearable by human beings. A semiconductor chip may be applied to Internet of Things.

In the entire specification, the same reference numerals may denote the same components. Accordingly, the same reference numerals or similar reference numerals may be described with reference to other drawings although they are not mentioned or described in corresponding drawings. Furthermore, although reference numerals are not shown, they may be described with reference to other drawings.

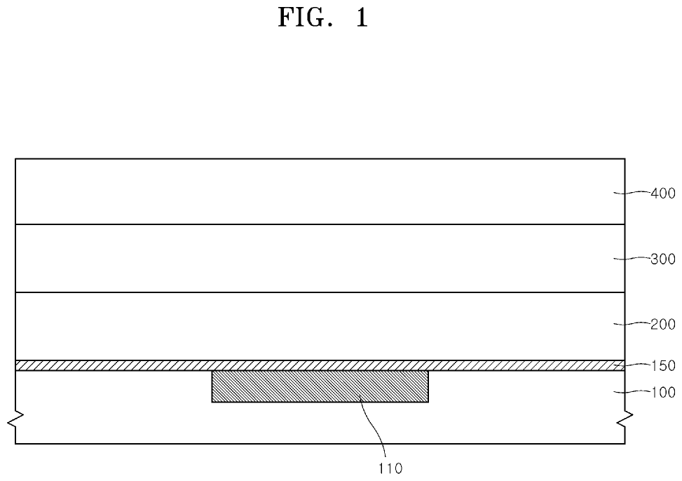

FIGS. 1 to 11 are diagrams illustrating a method of manufacturing a semiconductor device according to an embodiment. FIG. 1 is a cross-sectional view illustrating that photoresist layers 200, 300, and 400 are formed in a method of manufacturing a semiconductor device according to an embodiment.

Referring to FIG. 1, the method of manufacturing a semiconductor device may include process steps of forming a conductive bump on a substrate 100. The photoresist layers 200, 300, and 400 may be stacked on the substrate 100. The photoresist layers 200, 300, and 400 may include different photoresist substances. A first photoresist layer 200 may be formed on the substrate 100. A second photoresist layer 300 may be formed on the first photoresist layer 200. The first photoresist layer 200 may be formed to include a photoresist substance that is different from that of the second photoresist layer 300. The first photoresist layer 200 may be formed to have a thickness that is different from that of the second photoresist layer 300.

A third photoresist layer 400 may be further formed on the second photoresist layer 300. The third photoresist layer 400 may be formed to include a photoresist substance that is different from that of the second photoresist layer 300. Alternatively, the third photoresist layer 400 may be formed to include a photoresist substance that is different from that of the first photoresist layer 200. The photoresist layers 200, 300, and 400 may include a plurality of two or more layers. The structure in which the photoresist layers 200, 300, and 400 have been stacked as described above may be used as an element that provides a mold to form a conductive bump.

The substrate 100 may be a device substrate in which memory devices, semiconductor devices, or integrated circuits have been integrated. The memory devices may be volatile memory devices such as those using dynamic random access memory (DRAM). The memory devices may be nonvolatile memory devices such as those using NAND flash memory. The substrate 100 may be a semiconductor substrate including a semiconductor substance. The semiconductor substrate may be a substrate including silicon (Si) or germanium (Ge) or may be a substrate including silicon carbide (SiC), gallium arsenide (GaAs), indium arsenide (InAs), or indium phosphorous (InP). The substrate 100 may denote a semiconductor die. The substrate 100 may be an element on which semiconductor dies are mounted like a printed circuit board.

The substrate 100 may further include a conductive pad 110. The conductive pad 110 may be a bump land to which a conductive bump is to be connected. The conductive pad 110 may be some part of a wire that is electrically connected to an integrated circuit that is integrated within the substrate 100. The conductive pad 110 may be formed to include a metal substance, such as aluminum (Al).

A plating seed layer 150 may be further formed between the substrate 100 and the photoresist layers 200, 300, and 400. The plating seed layer 150 may be formed between the first photoresist layer 200 and the substrate 100. The plating seed layer 150 may be formed as a conductive layer for a process of plating a conductive bump. The plating seed layer 150 may include a metal substance, such as copper (Cu), nickel (Ni), or gold (Au). The plating seed layer 150 may include an under bump metal layer.

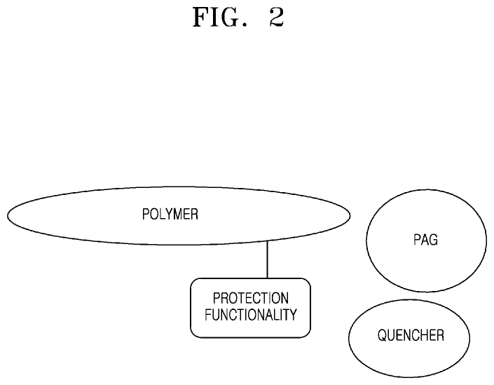

FIG. 2 is a diagram illustrating an example of a photoresist which may constitute the photoresist layers 200, 300, and 400 in FIG. 1.

Referring to FIGS. 1 and 2, the photoresist layers 200, 300, and 400 may be formed by applying various types of photoresists which are used in the photolithography technology. The photoresist may include a polymer, that is, a major element that constitutes film quality, a protection functionality that is combined with the polymer, and a photo add generator (PAG). The photoresist ay further include a quencher for adjusting the diffusion of acids.

The quencher may include an alkaline compound that is added to the photoresist to control or adjust the behavior of the acids that are generated from the PAG due to the reaction of the PAG to exposure light. The polymer may be a polymer having a carbon chain. The protection functionality may include polyhydroxystyrene. The PAG may be a compound that generates acids, such as hydrogen ions (H⁺), by exposure light. The generated acids may substitute the protection functionality with hydroxyl groups through a reaction of deprotecting the protection functionality. The substituted hydroxyl group has relatively high solubility with respect to a developer, that is, a weak alkali solution, so that a pattern of the photoresist layer may be formed in the form of an exposed pattern through a developing process.

Such a photoresist may be a photoresist for a KrF light source, a photoresist for an ArF light source, or a chemical amplification photoresist. The photoresist layer 200, 300, or 400 may be formed by coating, on the substrate 100, a photoresist solution in which the photoresist has been dissolved in a solvent and performing a soft bake that removes a certain part of the solvent.

The first photoresist layer 200 may be formed to include a first photoresist. The first photoresist may include a first polymer and a first protection functionality that is combined with the first polymer, and may include a first PAG and a first quencher. A first photoresist layer 200 may be formed by coating, on the substrate 100, a first photoresist solution in which the first photoresist has been dissolved in a first solvent and performing a soft bake. A second photoresist layer 300 may be formed by coating, on the first photoresist layer 200, a second photoresist solution in which a second photoresist has been dissolved in a second solvent and performing a soft bake. The second photoresist may include a second polymer and a second protection functionality that is combined with the second polymer, and may include a second PAG and a second quencher.

As described above, the first and second photoresist layers 200 and 300 may be formed by using the first and second photoresists that are different from each other. The second polymer may be the type of polymer that is different from the type of first polymer. The second polymer may be a polymer having a molecular weight that is different from that of the first polymer. The second protection functionality may be a protection functionality that is different from that of the first protection functionality. The number of second protection functionalities that have been combined with the second polymer may be different from the number of first protection functionalities that have been combined with the first polymer. The second PAG may be a PAG having an acid production rate that is different from that of the first PAG. The second quencher may be added to the second photoresist or the second photoresist layer 300 with a content that is different from the content of the first quencher added to the first photoresist or the first photoresist layer 200. The first and second photoresist layers 200 and 300 may be exposed and developed in the form of patterns having different forms.

Referring to FIG. 1, a third photoresist layer 400 may be further formed on the second photoresist layer 300. A third photoresist may include a third polymer and a third protection functionality that is combined with the third polymer, and may include a third PAG and a third quencher. The third photoresist layer 400 may be formed by coating, on the second photoresist layer 300, a third photoresist solution in which the third photoresist has been dissolved in a third solvent and performing a soft bake. The third photoresist may be different from the first photoresist or may be different from the second photoresist.

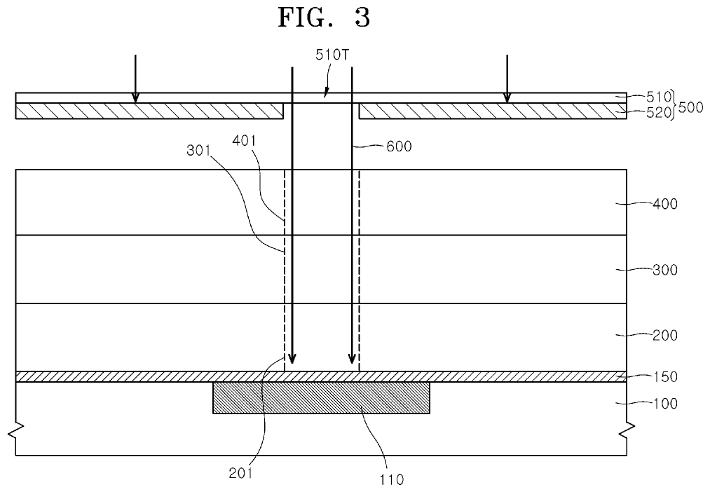

FIG. 3 is a cross-sectional view illustrating that the photoresist layers 200, 300, and 400 are exposed in a method of manufacturing a semiconductor device according to an embodiment.

Referring to FIG. 3, an exposure process step may be performed on a structure in which the photoresist layers 200, 300, and 400 have been stacked. Exposure light 600 may be radiated to some parts of the photoresist layers 200, 300, and 400. A photomask 500 may be introduced into the structure in which the photoresist layers 200, 300, and 400 have been stacked. The exposure light 600 having a pattern image of a light-transmitting region 5101 of the photomask 500 may be incident on the photoresist layers 200, 300, and 400. The photomask 500 may be a transmissive photomask that provides the pattern image that will be transferred as a shape of the light-transmitting region 510T. The photomask 500 may include a light-transmitting layer 510 including a transparent substrate and a light-blocking pattern 520 that is formed on the light-transmitting layer 510.

In FIG. 3, the photomask 500 is presented in the form of the transmissive photomask, but may have a reflective photomask form like a EUV mask. The exposure light may be laser light that is generated from a KrF light source, an ArF light source, or a EUV light source.

The some parts of the photoresist layers 200, 300, and 400 may be exposure regions 201, 301, and 401 on which the exposure light 600 is incident. The exposure light 600 that is radiated to the stack structure of the photoresist layers 200, 300, and 400 may be incident on the third exposure region 401 of the third photoresist layer 400, may be incident on the second exposure region 301 of the second photoresist layer 300 under the third exposure region 401 while passing through the third exposure region 401, may be incident on the first exposure region 201 of the first photoresist layer 200 under the second exposure region 301 while passing through the second exposure region 301, and may be radiated to the first exposure region 201. Because the exposure light 600 is radiated to the stack structure of the photoresist layers 200, 300, and 400, some parts of the photoresist layers 200, 300, and 400 or the exposure regions 201, 301, and 401 of the photoresist layers 200, 300, and 400 may be exposed at once. The exposure regions 201, 301, and 401 may be regions that are overlapped perpendicularly to each other because the exposure regions 201, 301, and 401 of the photoresist layers 200, 300, and 400 are radiated by a single exposure of exposure light 600. The exposure regions 201, 301, and 401 may be regions that have substantially the same width.

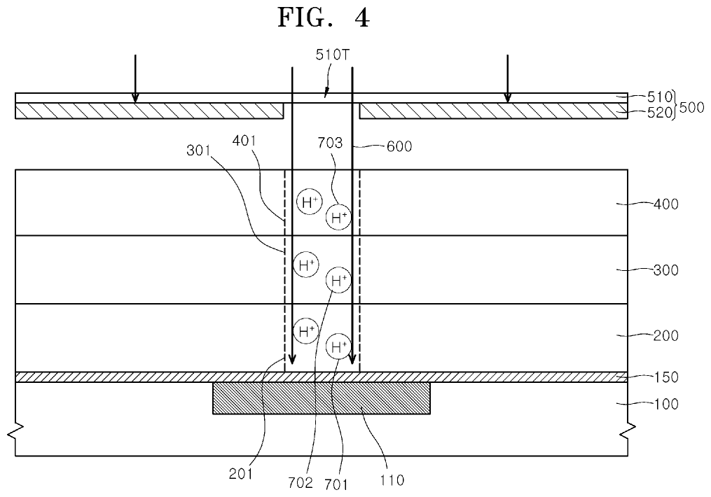

FIG. 4 is a cross-sectional view illustrating that acids 701, 702, and 703 have been generated in the photoresist layers 200, 300, and 400 in FIG. 3.

Referring to FIG. 4, the acids 701, 702, and 703 may be generated from PAGs through a reaction of the PAGs with the exposure light 600 that has been incident on the exposure regions 201, 301, and 401 of the photoresist layers 200, 300, and 400. The first add 701 is may be generated in the first exposure region 201 through a reaction of the first PAG within the first exposure region 201 of the first photoresist layer 200 with the incident exposure light 600. The second acid 702 may be generated in the second exposure region 301 through a reaction of the second PAG within the second exposure region 301 of the second photoresist layer 300 with the incident exposure light 600. The third acid 703 may be generated in the third exposure region 401 through a reaction of the third PAG within the third exposure region 401 of the third photoresist layer 400 with the incident exposure light 600. The amount of each of the first acid 701 generated, the second acid 702 generated, and the third add 703 generated may be different because the type and content of each of the first, second, and third PAGs included in the photoresist layers 200, 300, and 400, respectively, may be different.

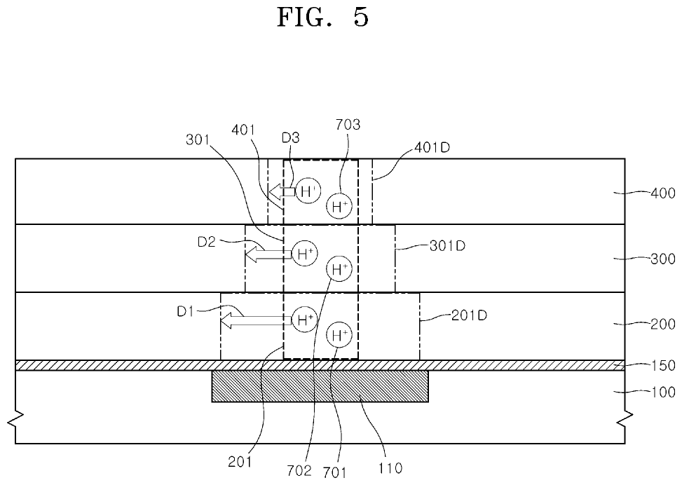

FIG. 5 is a cross-sectional view illustrating that the acids 701, 702, and 703 in FIG. 4 have been diffused.

Referring to FIG. 5, the acids 701, 702, and 703 that have been generated in the exposure regions 201, 301, and 401 of the photoresist layers 200, 300, and 400 may be diffused within the photoresist layers 200, 300, and 400. The acids 701, 702, and 703 may be further diffused to the outside of the exposure regions 201, 301, and 401. Diffusion regions 201D, 301D, and 401D into which the acids 701, 702, and 703 have been diffused may be formed as regions having wide widths by being more laterally extended than the exposure regions 201, 301, and 401 while including the exposure regions 201, 301, and 401. Because the type of photoresists that constitute the respective photoresist layers 200, 300, and 400 is different, diffusion distances D1, D2, and D3 at which the acids 701, 702, and 703 are diffused may be different from each other. Because the diffusion distances D1, D2, and D3 at which the acids 701, 702, and 703 are diffused may be different from each other, the widths of the diffusion regions 201D, 301D, and 401D may also be different from each other.

By making different the type of photoresists that constitute the photoresist layers 200, 300, and 400, respectively, a first diffusion distance D1 at which the first add 701 is diffused within the first photoresist layer 200 may be different from a second diffusion distance D2 at which the second acid 702 is diffused within the second photoresist layer 300. Accordingly, the first diffusion region 201D that is formed within the first photoresist layer 200 may have a width different from that of the second diffusion region 301D that is formed within the second photoresist layer 300. A third diffusion distance D3 at which the third acid 703 is diffused within the third photoresist layer 400 may be different from the second diffusion distance D2 or the first diffusion distance D1. A third diffusion region 401D that is formed within the third photoresist layer 400 may have a width different from that of the second diffusion region 301D or the first diffusion region 201D.

By making different the type of photoresists that constitute the photoresist layers 200, 300, and 400, respectively, the first diffusion distance D1 at which the first acid 701 is diffused within the first photoresist layer 200 may be longer than the second diffusion distance D2 at which the second acid 702 is diffused within the second photoresist layer 300. Accordingly, the first diffusion region 201D that is formed within the first photoresist layer 200 may have a greater width than the second diffusion region 301D that is formed within the second photoresist layer 300. The third diffusion distance D3 at which the third acid 703 is diffused within the third photoresist layer 400 may be shorter than the second diffusion distance D2 or the first diffusion distance D1. The third diffusion region 401D that is formed within the third photoresist layer 400 may have a smaller width than the second diffusion region 301D or the first diffusion region 201D.

The diffusion distances D1, D2, and D3 at which the acids 701, 702, and 703 are diffused into the photoresist layers 200, 300, and 400 may be different from each other by the influence of components or compositions of the photoresists. The diffusion distances D1, D2, and D3 of the acids may be different depending on type or content of a PAG that is included in a photoresist or an acid production rate, that is, the degree that acids are generated by a PAG. The diffusion distances D1, D2, and D3 of the acids may be different depending on the type or molecular weight of a polymer that constitutes a photoresist, the type of protection functionalities, or the number of protection functionalities that have been combined with a polymer. The diffusion distances D1, D2, and D3 of the acids may be different depending on the type or content of a quencher that is contained in a photoresist.

If the first diffusion region 201D is to be formed wider than the second diffusion region 301D by making longer the first diffusion distance D1 of the first acids 701 in the first photoresist layer 200 than the second diffusion distance D2 of the second acids 702 in the second photoresist layer 300, the first photoresist layer 200 may be formed of the first photoresist that includes the first polymer having a lower molecular weight than the second polymer included in the second photoresist that constitutes the second photoresist layer 300. Alternatively, the first photoresist layer 200 may be formed of the first photoresist that includes the first PAG having a higher acid production rate than the second PAG that is included in the second photoresist. Alternatively, the first photoresist may be formed so that the number of first protection functionalities that are combined with the first polymer is smaller than the number of second protection functionalities that are combined with the second polymer. Alternatively, the first photoresist may be formed so that the first quencher is included with a higher content than the content of the second quencher of the second photoresist.

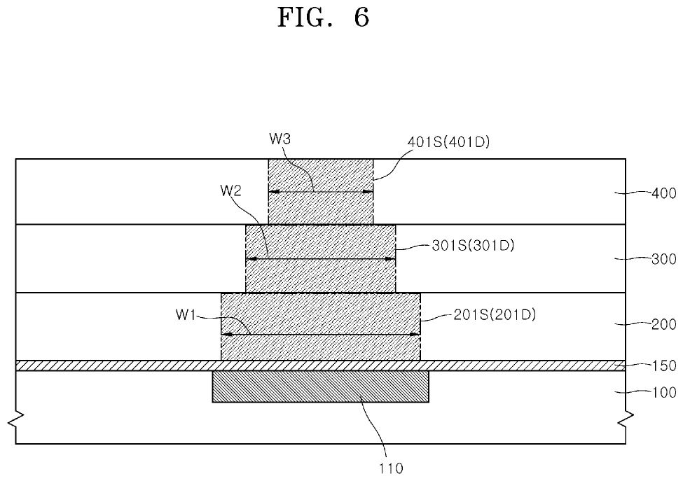

FIG. 6 is a cross-sectional view illustrating that dissolvable regions 201S, 301S, and 401S have been formed in the diffusion regions 201D, 301D, and 401D in FIG. 5.

Referring to FIGS. 5 and 6, the acids 701, 702, and 703 that have been generated or diffused within the diffusion regions 201D, 301D, and 401D of the photoresist layers 200, 300, and 400 may substitute protection functionalities in the state in which the protection functionalities have relatively high solubility with respect to a developer through a reaction of deprotecting the protection functionalities of polymers. By the deprotection reaction, the protection functionalities may be substituted with hydroxyl groups having relatively high solubility with respect to the developer including a weak alkali solution. Accordingly, the diffusion regions 201D, 301D, and 401D may be changed into the dissolvable regions 201S, 301S, and 401S which may be dissolved in the developer. As first and second dissolvable regions 201S and 301S are formed, a third dissolvable region 401S may also be formed in the third photoresist layer 400. The dissolvable regions 201S, 301S, and 401S may be regions in which solubility to the developer is relatively high compared to a photoresist that has not been exposed. To accelerate the forming of the dissolvable regions 201S, 301S, and 401S as described above, a post exposure bake process may be performed on the photoresist layers 200, 300, and 400.

The dissolvable regions 201S, 301S, and 401S may have different widths because the diffusion regions 201D, 301D, and 401D of the photoresist layers 200, 300, and 400 have different widths. The first dissolvable region 201S having a first width W1 may be formed in the first photoresist layer 200. The second dissolvable region 301S having a second width W2 may be formed in the second photoresist layer 300. The second width W2 of the second dissolvable region 301S may be different from the first width W1. The third dissolvable region 401S having a third width W3 may be formed in the third photoresist layer 400. Accordingly, the second width W2 may be smaller than the first width W1, and the third width W3 may be smaller than the second width W2.

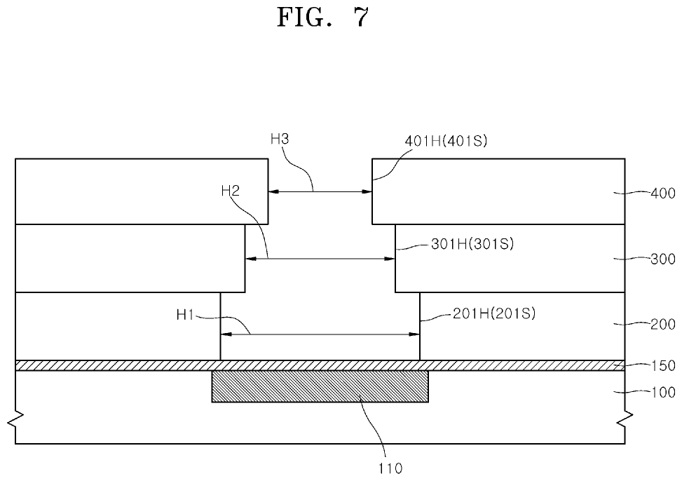

Because the dissolvable regions 201S, 301S, and 401S are formed by the deprotection reactions of the acids 701, 702, and 703 and the protection functionalities, the dissolvable regions 201S, 301S, and 401S may have substantially the same widths as the diffusion regions 201D, 301D, and 401D of the photoresist layers 200, 300, and 400 in which the adds 701, 702, and 703 have been distributed, respectively, FIG. 7 is a cross-sectional view illustrating that openings 201H, 301H, and 401H in a method of manufacturing a semiconductor device according to an embodiment are formed in photoresist layers.

Referring to FIGS. 6 and 7, a developing process using a developer may be performed on the structure in which the photoresist layers 200, 300, and 400 have been stacked. The dissolvable regions 201S, 301S, and 401S of the photoresist layers 200, 300, and 400 may be developed and removed by the developer. As the dissolvable regions 201S, 301S, and 401S are removed from the photoresist layers 200, 300, and 400, openings 201H, 301H, and 401H may be formed at locations of the dissolvable regions 201S, 301S, and 401S. In a process of developing the first and second dissolvable regions 201S and 301S, the third dissolvable region 401S is also developed, so that the third opening 401H may be formed along with the first and second openings 201H and 301H. The openings 201H, 301H, and 401H may be formed as empty spaces according to shapes of the dissolvable regions 201S, 301S, and 401S.

As the third dissolvable region 401S is developed from the third photoresist layer 400 by the developer, the third opening 401H may be formed in the third photoresist layer 400. As the second dissolvable region 301S is developed from the second photoresist layer 300 by the developer that is introduced through the third opening 401H, the second opening 301H may be formed in the second photoresist layer 300. As the first dissolvable region 201S is developed from the first photoresist layer 200 by the developer that is introduced through the third and second openings 401H and 301H, the first opening 201H may be formed in the first photoresist layer 200.

The first opening 201H may have a fourth width H1 according to the first width W1 of the first dissolvable region 201S. The fourth width H1 of the first opening 201H may have substantially the same size as the first width W1. The second opening 301H may have a fifth width H2 according to the second width W2 of the second dissolvable region 301S. The third opening 401H may have a sixth width H3 according to the third width W3 of the third dissolvable region 401S. Because the dissolvable regions 201S, 301S, and 401S may have different widths W1, W2, and W3, the openings 201H, 301H, and 401H may have the widths H1, H2, and H3 having different sizes according to the widths W1, W2, and W3 of the dissolvable regions 201S, 301S, and 401S, respectively. Accordingly, a shape in which the openings 201H, 301H, and 401H overlap may have a side profile having a staggered or stair shape. The shape in which the openings 201H, 301H, and 401H overlap may have a hole shape the widths of which are different in a direction that becomes distant from the substrate 100. The shape in which the openings 201H, 301H, and 401H overlap may have a hole shape the widths of which are reduced as the widths become distant from the substrate 100.

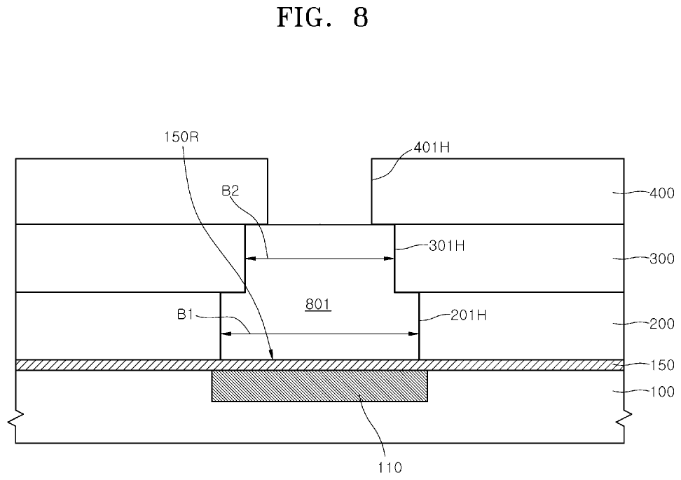

FIG. 8 is a cross-sectional view illustrating forming a conductive bump 801 in a method of manufacturing a semiconductor device according to an embodiment.

Referring to FIGS. 7 and 8, the conductive bump 801 that fills the first opening 201H of the first photoresist layer 200 and the second opening 301H of the second photoresist layer 300 may be formed. Because the conductive bump 801 fills the first and second openings 201H and 301H having different widths H1 and H2, the conductive bump 801 may have different widths in a direction that becomes distant from the substrate 100 or may have a shape in which the widths are changed. The conductive bump 801 may be formed in a form in which a seventh width B1 of a bottom part of the conductive bump 801, which is relatively dose to the substrate 100, is different from an eighth width 32 of a top part of the conductive bump 801, which is relatively distant from the substrate 100. The conductive bump 801 may be formed in a form in which the seventh width 31 of the bottom part of the conductive bump 801, which is relatively dose to the substrate 100, has a greater width than the eighth width B2 of the top part of the conductive bump 801, which is relatively distant from the substrate 100.

The conductive bump 801 may be formed to include metal, such as copper (Cu). The conductive bump 801 may be formed by a plating process. The conductive bump 801 may be plated in some part 150R of the plating seed layer 150, which is exposed to the first and second openings 201H and 301H. The plating process may be performed so that the conductive bump 801 is further extended by filling the third opening 401H.

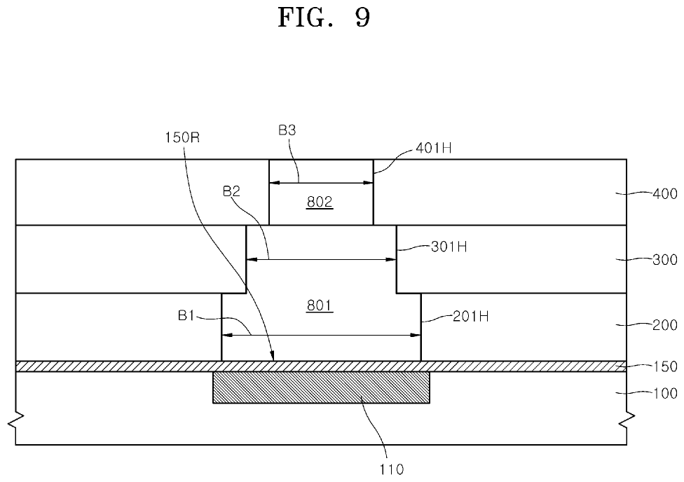

FIG. 9 is a cross-sectional view illustrating that a solder layer 802 is formed on the conductive bump 801 in FIG. 8.

Referring to FIGS. 8 and 9, the solder layer 802 that fills the third opening 40111 of the third photoresist layer 400 may be formed on the conductive bump 801. The solder layer 802 may be formed by a plating process. Because the solder layer 802 fills the third opening 401H, the solder layer 802 may be formed to have a ninth width B3 different from the widths of the conductive bump 801.

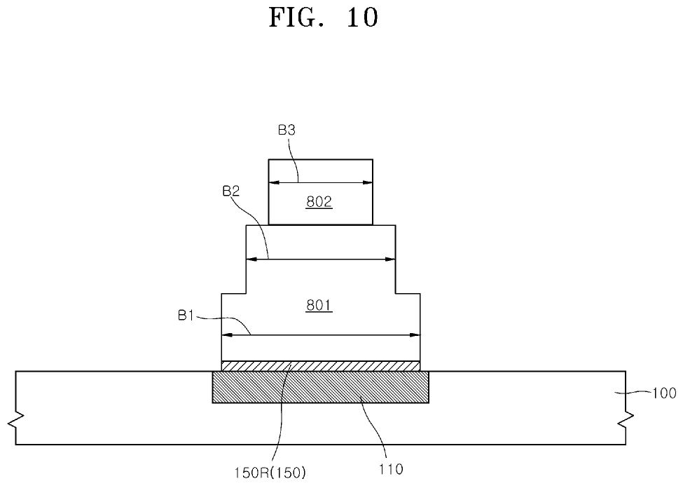

FIG. 10 is a cross-sectional view illustrating that the photoresist layers 200, 300, and 400 have been removed from the conductive bump 801 in FIG. 9.

Referring to FIG. 10, the photoresist layers 200, 300, and 400 may be removed from the substrate 100 in which the conductive bump 801 and the solder layer 802 have been formed. Other some parts of the plating seed layer 150, which are exposed as the photoresist layers 200, 300, and 400 are removed, may be selectively removed.

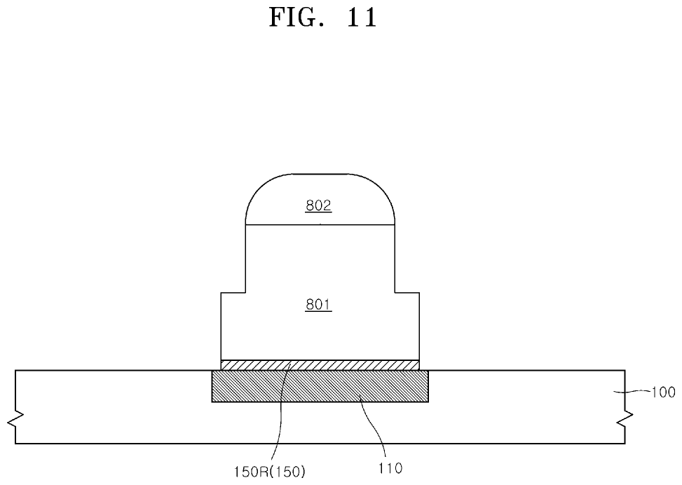

FIG. 11 is a cross-sectional view illustrating that the solder layer 802 in FIG. 10 has been reflowed.

Referring to FIG. 11, the solder layer 802 may be modified into a form that covers a top surface of the conductive bump 801 by reflowing the solder layer 802.

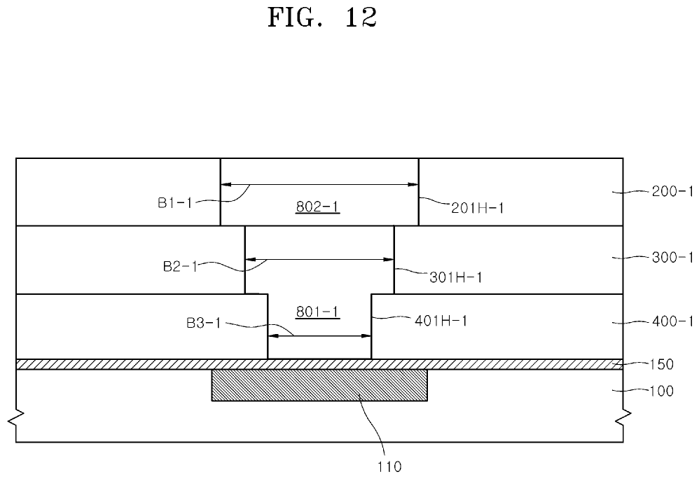

FIG. 12 is a cross-sectional view illustrating forming a conductive bump 801-1 in a method of manufacturing a semiconductor device according to an embodiment.

Referring to FIG. 12, a shape of the conductive bump 801-1 may be formed into a modified shape by changing a stack sequence or forming sequence of the photoresist layers 400-1, 300-1, and 200-1 that are stacked on the substrate 100. Furthermore, a solder layer 802-1 may be formed to have a tenth width B1-1 that is greater than the width of the conductive bump 801-1. A third photoresist layer 400-1 may be formed at a location that is relatively close to the substrate 100. A second photoresist layer 300-1 may be formed on the third photoresist layer 400-1. A first photoresist layer 200-1 may be formed on the second photoresist layer 300-1.

By exposing and developing the stack structure of the photoresist layers 400-1, 300-1, and 200-1, a third opening 401H-1 may be formed in the third photoresist layer 400-1, a second opening 301H-1 may be formed in the second photoresist layer 300-1, and a first opening 201H-1 may be formed in the first photoresist layer 200-1. The third, second, and first openings 401H-1, 301H-1, and 201H-1 may be formed to have different widths. The third, second, and first openings 401H-1, 301H-1, and 201H-1 may be formed to have widths that are sequentially relatively reduced.

The conductive bump 801-1 that fills the third and second openings 401H-1 and 301H-1 may be formed. The solder layer 802-1 that fills the first opening 201H-1 may be formed on the conductive bump 801-1. The conductive bump 801-1 may include a bottom part having an eleventh width B3-1 and a top part having a twelfth width 132-1. The eleventh width B3-1 of the bottom part of the conductive bump 801-1 may be smaller than the twelfth width 132-1 of the top part of the conductive bump 801-1.

As described above, the side profile of the conductive bump 801-1 may have a staggered or stair shape having various forms by changing the stack sequence or forming sequence of the photoresist layers 400-1, 300-1, and 200-1 that are stacked on the substrate 100.

Referring to FIG. 1, the first photoresist layer 200 may be formed on the substrate 100, and the second photoresist layer 300 may be formed on the first photoresist layer 200. The first dissolvable region 201S having the first width W1 may be formed in the first photoresist layer 200 and the second dissolvable region 301S having the second width W2 different from the first width W1 may be formed in the second photoresist layer 300 as presented in FIG. 6 by radiating the exposure light 600 to some parts of the second and first photoresist layers 300 and 200 as presented in FIG. 3.

As presented in FIG. 9, the conductive bump 801 that fills the first and second openings 201H and 301H may be formed.

As presented in FIG. 1, the third photoresist layer 400 may be further formed on the second photoresist layer 300. As presented in FIGS. 3 and 6, as the first and second dissolvable regions 201S and 301S are formed, the third dissolvable region 401S may be formed in the third photoresist layer 400. As presented in FIGS. 6 and 7, the third opening 401H may be formed by developing the third dissolvable region 401S while forming the first and second openings 201H and 301H.

Referring to FIGS. 4 and 5, the first photoresist layer 200 may be formed on the substrate 100, and the second photoresist layer 300 may be formed on the first photoresist layer 200. The second diffusion distance D2 at which the second acid 702 that is generated by the exposure light 600 is diffused in the second photoresist layer 300 may be different from the first diffusion distance D1 at which the first acid 701 that is generated by the exposure light 600 is diffused in the first photoresist layer 200. Accordingly, when the exposure light 600 is radiated to some parts of the second and first photoresist layers 300 and 200 as presented in FIG. 3, the first dissolvable region 201S having the first width W1 may be formed in the first photoresist layer 200 and the second dissolvable region 301S having the second width W2 different from the first width W1 may be formed in the second photoresist layer 300 as presented in FIG. 6.

The third photoresist layer 400 in which the third diffusion distance D3 at which the third acid 703 that is generated by the exposure light 600 is diffused is different from the first diffusion distance D1 or the second diffusion distance D2 may be formed on the second photoresist layer 300. The third dissolvable region 401S may be formed in the third photoresist layer 400 while forming the first and second dissolvable regions 201S and 301S as presented in FIG. 6.

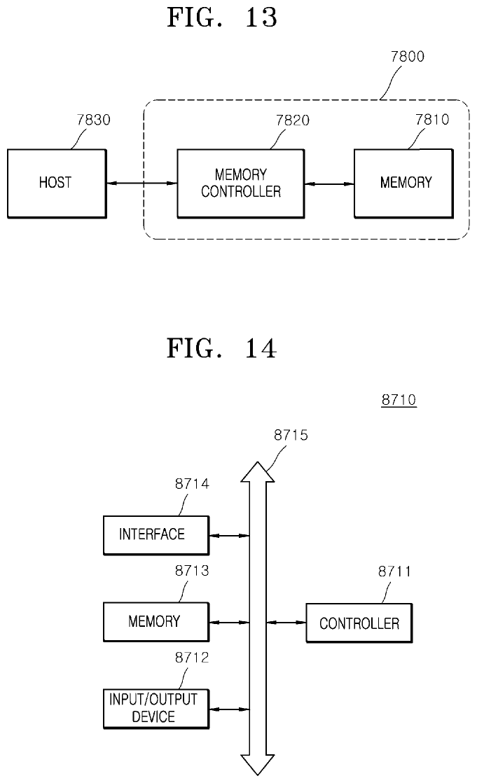

FIG. 13 is a block diagram illustrating an electronic system including a memory card 7800 employing at least one semiconductor device according to an embodiment. The memory card 7800 includes a memory device 7810 such as a nonvolatile memory device, and a memory controller 7820. The memory device 7810 and the memory controller 7820 may store data or read out the stored data. At least one of the memory device 7810 and the memory controller 7820 may include at least one of the semiconductor packages according to the embodiments.

The memory device 7810 may be a nonvolatile memory device to which the technology of the embodiments of the present disclosure is applied. The memory controller 7820 may control the memory device 7810 such that stored data is read out or data is stored in response to a read/write request from a host 7830.

FIG. 14 is a block diagram illustrating an electronic system 8710 including at least one semiconductor device according to an embodiment. The electronic system 8710 may include a controller 8711, an input/output device 8712, and a memory device 8713. The controller 8711, the input/output device 8712, and the memory device 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory device 8713 may include at least one of the semiconductor packages according to the embodiments of the present disclosure. The input/output device 8712 may include at least one selected among a keypad, a keyboard, a display device, a touchscreen and so forth. The memory device 8713 is a device for storing data. The memory device 8713 may store data and/or commands to be executed by the controller 8711, and the like.

The memory device 8713 may include volatile memory such as DRAM and/or nonvolatile memory such as flash memory. For example, flash memory may be mounted to an information processing system such as a mobile terminal or a desktop computer. The flash memory may constitute a solid state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer, or a logic system performing various functions. For example, the mobile system may be any one of a personal digital assistant (PDA), a portable computer, a tablet computer, a mobile phone, a smart phone, a wireless phone, a laptop computer, a memory card, a digital music system, and an information transmission/reception system.

If the electronic system 8710 is an equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution), or Wibro (wireless broadband Internet).

Only a limited number of possible embodiments for the present disclosure have been described above. A person having ordinary knowledge in the art to which the present disclosure pertains will understand that the present teachings may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure,

What is claimed is:

1. A method of manufacturing a semiconductor device, the method comprising:
forming a first photoresist layer on a substrate;
forming a second photoresist layer on the first photoresist layer;
forming a first dissolvable region having a first width in the first photoresist layer and a second dissolvable region having a second width different from the first width in the second photoresist layer by radiating exposure light to some parts of the second and first photoresist layers;
forming a second opening in the second photoresist layer and a first opening in the first photoresist layer by developing the second dissolvable region and the first dissolvable region; and
forming a conductive bump that fills the first and second openings.

2. The method of claim 1, wherein the first photoresist layer comprises a photoresist different from a photoresist of the second photoresist layer.

3. The method of claim 1, wherein:
the first photoresist layer comprises a first polymer, a first photo acid generator (PAG), and a first protection functionality that is combined with the first polymer, and
the second photoresist layer comprises a second polymer, a second PAG, and a second protection functionality that is combined with the second polymer.

4. The method of claim 3, wherein the second polymer has a molecular weight different from a molecular weight of the first polymer.

5. The method of claim 3, wherein the second PAG has an acid production rate different from an acid production rate of the first PAG.

6. The method of claim 3, wherein a number of second protection functionalities that are combined with the second polymer is different from a number of first protection functionalities that are combined with the first polymer.

7. The method of claim 3, wherein:
the first photoresist layer further comprises a first quencher that adjusts a diffusion of acid generated from the first PAG, and
the second photoresist layer further comprises a second quencher that has a content different from a content of the first quencher.

8. The method of claim 1, further comprising:
forming a third photoresist layer on the second photoresist layer;
forming a third dissolvable region in the third photoresist layer while forming the first and second dissolvable regions;
forming a third opening by developing the third dissolvable region while forming the first and second openings; and
forming, on the conductive bump, a solder layer that fills the third opening.

9. The method of claim 1, further comprising forming a plating seed layer between the first photoresist layer and the substrate, wherein the conductive bump is plated in some part of the plating seed layer, which is exposed by the first and second openings.

10. The method of claim 1, wherein the first photoresist layer is formed to have a thickness different from a thickness of the second photoresist layer.

11. A method of manufacturing a semiconductor device, the method comprising:
forming a first photoresist layer on a substrate;
forming, on the first photoresist layer, a second photoresist layer in which a second diffusion distance at which a second acid, that is generated by exposure light incident on a part of the second photoresist layer, is diffused is different from a first diffusion distance at which a first acid, that is generated by the exposure light incident on a part of the first photoresist layer, is diffused in the first photoresist layer;
forming, as a result of the incident exposure light, a first dissolvable region having a first width in the first photoresist layer and a second dissolvable region having a second width different from the first width in the second photoresist layer;
forming a second opening in the second photoresist layer and a first opening in the first photoresist layer by developing the second dissolvable region and the first dissolvable region; and
forming a conductive bump that fills the first and second openings.

12. The method of claim 11, further comprising:
forming, on the second photoresist layer, a third photoresist layer in which a third diffusion distance at which a third acid, that is generated by the exposure light incident on a part of the third photoresist layer, is diffused is different from the first diffusion distance; and
forming a third dissolvable region in the third photoresist layer while forming the first and second dissolvable regions;
forming a third opening by developing the third dissolvable region while forming the first and second openings; and
forming, on the conductive bump, a solder layer that ills the third opening.

13. The method of claim 11, further comprising forming a plating seed layer between the first photoresist layer and the substrate, wherein the conductive bump is plated in some part of the plating seed layer, which is exposed by the first and second openings.

14. The method of claim 11, wherein the first photoresist layer is formed to have a thickness different from a thickness of the second photoresist layer.

15. The method of claim 11, wherein the first photoresist layer comprises a photoresist different from a photoresist of the second photoresist layer.

16. The method of claim 11, wherein:
the first photoresist layer comprises a first polymer, a first photo acid generator (PAG), and a first protection functionality that is combined with the first polymer, and
the second photoresist layer comprises a second polymer, a second PAG, and a second protection functionality that is combined with the second polymer.

17. The method of claim 16, wherein:
the first photoresist layer further comprises a first quencher that adjusts a diffusion of acid generated from the first PAG, and
the second photoresist layer further comprises a second quencher that has a content different from a content of the first quencher.
